(19) United States
(12) Patent Application Publication
(10) Pub. No.: US 2012/0043118 A1
(43) Pub. Date: Feb. 23, 2012

(54) ADHESIVE RESIN COMPOSITION, AND LAMINATE AND FLEXIBLE PRINTED WIRING BOARD USING THE SAME

(75) Inventors: Shingo Kaimori, Osaka-shi (JP); Jun Sugawara, Osaka-shi (JP); Akira Mizoguchi, Osaka-shi (JP); Syoung Asai, Kouga-shi (JP); Takuma Yoshisaka, Kouga-shi (JP); Naota Uenishi, Osaka-shi (JP)

(73) Assignees: SUMITOMO ELECTRIC PRINTED CIRCUITS, INC., Kouga-shi, Shiga (JP); SUMITOMO ELECTRIC INDUSTRIES, LTD., Osaka-shi, Osaka (JP)

(21) Appl. No.: 13/318,300

(22) PCT Filed: Mar. 26, 2010
(86) PCT No.: PCT/JP2010/055312

§ 371 Date: Oct. 31, 2011

(30) Foreign Application Priority Data
Apr. 30, 2009 (JP) 2009-111505

(51) Int. Cl. H05K 1/02; C09J 163/00; C08K 5/5399; B32B 7/12

(52) U.S. Cl. 174/254; 428/355 EP; 525/115; 525/150; 524/115

(57) ABSTRACT

Provided is an adhesive resin composition containing (A) an epoxy resin and/or a phenoxy resin; (B) an epoxy-containing styrene copolymer containing a monomer unit having an epoxy group and a styrene monomer unit; (C) a thermoplastic resin; and (D) a curing agent, in which the content percentage of the epoxy-containing styrene copolymer (B) relative to the total amount of the resin components contained in the adhesive resin composition is 3% to 25% by mass. The adhesive resin composition is a halogen-free adhesive composition having good flame retardancy and a high peel strength. Also provided are a laminate and a flexible printed wiring board that use the adhesive resin composition.

### CROSS-REFERENCE TO RELATED APPLICATION

The present application is a national phase application of PCT Application No. PCT/JP2010/055312, filed on Mar. 26, 2010, and claims priority to Japanese Application No. 2009-111505, filed on Apr. 30, 2009, the entire contents of which are herein incorporated by reference.

### TECHNICAL FIELD

The present invention relates to an adhesive resin composition suitable for use in a flexible printed wiring board such as a flexible copper-clad laminated board, and a flexible printed wiring board and laminates such as an adhesive sheet and a coverlay film using the adhesive resin composition.

### BACKGROUND ART

In general, flexible printed wiring boards have a basic structure in which a copper foil or the like is bonded with an adhesive to one surface or both surfaces of an insulating film used as a base material, the insulating film being composed of a heat-resistant film such as a polyimide film. Hitherto, an adhesive obtained by mixing a flame retardant with a blending resin containing an epoxy resin, a phenoxy resin, or the like and a thermoplastic resin such as acryl, polyamide, or polyester has been used as such an adhesive. The epoxy resin and the phenoxy resin (hereinafter, may be generically referred to as “epoxy/phenoxy resin” in the case where these resins are not particularly distinguished from each other) have a function of imparting heat resistance, chemical resistance, and mechanical strength. The thermoplastic resin has a function of imparting a high adhesion property and flexibility.

For the flame retardant, high flame retardancy corresponding to the VTM-0 class or the V-0 class in the Underwriters' Laboratories (UL) 94 standard is required. Hitherto, halogen flame retardants have been used. Recently, however, in view of the problems of environmental pollution, phosphorus flame retardants such as phosphoric esters, phosphate amides, melamine polyphosphate, ammonium polyphosphate, 9,10-dihydro-9-oxa-10-phosphaphenanthrene-10-oxide and derivatives thereof, and phosphazene compounds have been used instead of the halogen flame retardants.

However, in order to satisfy high flame retardancy corresponding to the VTM-0 class or the V-0 class in the UL-94 standard by using only these phosphorus flame retardants, it is necessary to mix a large amount of a phosphorus flame retardant as compared with the case where a halogen flame retardant is used. However, with the increase in the amount of phosphorus flame retardant mixed, the adhesion property and the mechanical strength decrease.

In order to solve this problem, recently, it has been proposed that the amount of phosphorus flame retardant mixed be reduced by using a resin that utilizes a flame retardant effect due to phosphorus.

For example, PTL 1 (Japanese Unexamined Patent Application Publication No. 2003-176470) has proposed a halogen-free adhesive resin composition in which the phosphorus content percentage in the composition is controlled to be 2% by weight or more by using a phosphorus-containing epoxy resin and further using a phosphorus-containing phenoxy resin as one component of thermoplastic resins.

PTL 2 (Japanese Unexamined Patent Application Publication No. 2005-248134) has proposed, as a halogen-free adhesive resin composition having good flame retardancy, an adhesive resin composition containing a halogen-free epoxy resin; a thermoplastic resin and/or synthetic rubber such as a polyester resin, an acrylic resin, and acrylonitrile-butadiene rubber having carboxyl groups; a curing agent; and a phosphorus-containing compound such as a phosphoric ester compound.

Furthermore, PTL 3 (International Publication No. WO01/60938) has proposed an adhesive resin composition containing an epoxy resin, a curing agent, and a high polymer compound incompatible with the epoxy resin. As the high polymer compound incompatible with the epoxy resin, an acrylic copolymer having a functional group such as an epoxy group and having a weight-average molecular weight of 100,000 or more is used.

### SUMMARY OF INVENTION

### Technical Problem

As described above, various halogen-free adhesive resin compositions for a flexible printed wiring board, the adhesive resin compositions having good flame retardancy, have been proposed. However, in order to realize the expansion of applications of the flexible printed wiring boards to, for example, motor vehicles, a further reduction in weight of the flexible printed wiring boards, and the storage in a narrow space, it is necessary to further improve flame retardancy, heat resistance, chemical resistance, and mechanical strength. As means for realizing these requirements, an increase in the amount of epoxy/phenoxy resin, incorporation of a phosphorus-containing epoxy/phosphorus-containing phenoxy resin, and incorporation of an epoxy/phenoxy resin having a higher molecular weight are conceivable. However, in this case, new problems such as a decrease in the adhesion property and poor compatibility occur. Even if components with poor compatibility are dispersed by forced mixing, for example, the mixing components are separated during coating, or aggregation and gelation occur, resulting in an uneven coating. As a result, desired characteristics such as the adhesive strength are not obtained or the characteristics significantly vary between products.

The present invention has been made in view of the above circumstance. An object of the present invention is to provide a halogen-free adhesive resin composition which has good flame retardancy and which also has a high peel strength, and a laminate and a flexible printed wiring board using the adhesive resin composition.

### Solution to Problem

As a result of extensive studies, the inventors of the present invention found that the adhesion property can be significantly improved by incorporating an epoxy-containing styrene copolymer in a specific amount without impairing the compatibility among an epoxy/phenoxy resin, a thermoplastic resin, and the epoxy-containing styrene copolymer. This finding resulted in completion of the present invention.

Specifically, an adhesive resin composition of the present invention contains (A) an epoxy resin and/or a phenoxy resin; (B) an epoxy-containing styrene copolymer containing a monomer unit having an epoxy group and a styrene monomer unit; (C) a thermoplastic resin; and (D) a curing agent, wherein the content percentage of the epoxy-containing styrene copolymer (B) relative to the total amount of the resin components contained in the resin composition is 3% to 25% by mass.

The epoxy-containing styrene copolymer (B) preferably has a weight-average molecular weight of 5,000 to 120,000, and the content percentage of the styrene monomer unit in the (B) is preferably 35% to 98% by mass. The content percentage of the styrene monomer unit relative to the total amount of the resin components is preferably 1% to 20% by mass.

The epoxy-containing styrene copolymer (B) may further contain an acrylonitrile monomer unit. The weight per epoxy equivalent is preferably 250 g/eq or more and 3,500 g/eq or less, and a monomer having an epoxy group is preferably glycidyl (meth)acrylate.

The epoxy resin and/or phenoxy resin (A) is preferably a phosphorus-containing epoxy resin and/or a phosphorus-containing phenoxy resin from the standpoint of imparting flame retardancy. Furthermore, preferably, the adhesive resin composition further contains a phosphorus flame retardant, and the phosphorus content percentage relative to the solid content of the resin composition is 3.1% to 4.5% by mass.

A laminate of the present invention includes a base material film and an adhesive layer disposed on the base material film, the adhesive layer being composed of any of the above adhesive resin compositions of the present invention. Furthermore, a flexible printed wiring board including this laminate is also included in the present invention.

### Advantageous Effect of Invention

The adhesive resin composition of the present invention is good in terms of compatibility among resin components mixed, and thus it is possible to provide a one-part adhesive solution that is good in terms of coating property and storage stability, and that can exhibit desired adhesive strength, mechanical properties and chemical properties.

### DESCRIPTION OF EMBODIMENTS

Embodiments of the present invention will now be described. However, it is to be understood that the embodiments disclosed herein are illustrative in all respects and are not restrictive. It is intended that the scope of the present invention is defined by Claims and includes equivalents of Claims and all modifications within the scope of Claims.

### [Adhesive Resin Composition]

An adhesive resin composition of the present invention contains (A) an epoxy resin and/or a phenoxy resin; (B) an epoxy-containing styrene copolymer containing a monomer unit having an epoxy group and a styrene monomer unit; (C) a thermoplastic resin; and (D) a curing agent, in which the content percentage of the epoxy-containing styrene copolymer (B) in the resin components is specified within a certain range.

The components will be described in order.
(A) Epoxy Resin and/or Phenoxy Resin

The epoxy resin used in the present invention may be any resin as long as the resin has at least two epoxy groups in one molecule. Examples thereof include bisphenol A epoxy resins, bisphenol F epoxy resins, glycidyl ether epoxy resins, glycidyl ester epoxy resins, glycidylamine epoxy resins, novolac epoxy resins, and cresol novolak epoxy resins. Preferably, examples thereof include phosphorus-containing epoxy resins in which phosphorus atoms are bonded to any of these epoxy resins using a reactive phosphorus compound. Such phosphorus-containing epoxy resins are preferable because these phosphorus-containing epoxy resins exhibit a flame retardant effect due to phosphorus, and thus the content of a non-halogen flame retardant can be reduced, and consequently, it is possible to prevent a decrease in the adhesive strength and the mechanical strength due to the incorporation of the flame retardant. However, with an increase in the phosphorus content, the compatibility with other resins tends to decrease. Therefore, in the case of a phosphorus-containing epoxy resin or a phosphorus-containing phenoxy resin, the phosphorus content percentage relative to the mass of an epoxy resin or phenoxy resin to which phosphorus is incorporated is preferably 2% to 6% by mass.

Commercially available phosphorus-containing epoxy resins and phosphorus-containing phenoxy resins may be used. Examples thereof include FX289, FX305, and ERF001 manufactured by Tohto Kasei CO., LTD., and EPICLON EXA-9710 manufactured by DIC Corporation.

The same as the above applies to epoxy resins having high molecular weights and classified as phenoxy resins. Adhesives containing a phenoxy resin or an epoxy resin having a high molecular weight are preferable. The reasons for this are as follows. Such adhesives are advantageous, for example, in that it is easy to control the cure extent in a coverlay or an adhesive sheet in a semi-hardened state, and that the lifetime is long. Also, such adhesives are advantageous, for example, in that a desired adhesion property and desired mechanical properties can be obtained by heating for a short time, and thus high productivity can be achieved in the production of a copper clad laminate (CCL) and the production of a flexible printed circuit (FPC), and that such adhesives have good flow characteristics.

The weight-average molecular weights of the epoxy resin and the phenoxy resin are not particularly limited. However, with an increase in the molecular weight, the compatibility of the epoxy resin with other resins tends to decrease. Regarding the phenoxy resin, this tendency is stronger. Therefore, it is preferable to appropriately determine the weight-average molecular weights of these resins in consideration of the relationship with the compatibility in accordance with the types of resins used.

The epoxy resins and the phenoxy resins described above may be used alone or as a mixture of two or more resins. An epoxy resin and a phenoxy resin may be mixed and used.

The content percentage of the component (A) in the adhesive resin composition of the present invention is not particularly limited. In order to achieve satisfactory heat resistance, chemical resistance, and mechanical properties, among the resin components contained in the composition, the content percentage of the component (A) is preferably the largest. Specifically, the content percentage of the component (A) is preferably 40% to 70% by mass relative to the mass of the resin components contained in the resin composition (i.e., the total amount of the component (A), the component (B), the component (C), and, if another resin is optionally contained, the resin).

### (B) Epoxy-Containing Styrene Copolymer

The epoxy-containing styrene copolymer used in the present invention is a copolymer obtained by copolymerizing a monomer having an epoxy group, a styrene monomer, and as required, another copolymerizable unsaturated monomer.

The monomer having an epoxy group may be any compound as long as the compound has a copolymerizable unsaturated bond and an epoxy group in a side chain thereof. Glycidyl group-containing unsaturated monomers are preferably used. Specific examples thereof include glycidyl esters of unsaturated carboxylic acids, such as glycidyl acrylate, glycidyl methacrylate, itaconic acid monoglycidyl ester, and butene tricarboxylic acid monoglycidyl ester; and glycidyl ethers such as vinyl glycidyl ether, allyl glycidyl ether, and glycidyloxyethyl vinyl ether. Among these, glycidyl acrylate and glycidyl methacrylate are preferably used.

Examples of the styrene monomer include not only styrene, but also nucleus-substituted styrenes such as o-, m-, and p-methylstyrenes, dimethylstyrene, ethylstyrene, and chlorostyrene, and styrene derivatives such as α-methylstyrene, α-chlorostyrene, and β-chlorostyrene. Among these monomers, styrene is preferable.

Examples of the other copolymerizable unsaturated monomer include, but are not particularly limited to, olefins such as ethylene and propene; vinyl esters such as vinyl acetate, vinyl propionate, and vinyl benzoate; α, β-unsaturated carboxylic acids such as acrylic acid, methacrylic acid, itaconic acid, and maleic acid; salts of these α, β-unsaturated carboxylic acids; alkyl esters of (meth)acrylic acids such as methyl (meth)acrylate, ethyl (meth)acrylate, and propyl (meth)acrylate; amides such as acrylamide and methacrylamide; and nitriles such as acrylonitrile. These copolymerizable unsaturated monomers are used in combination with the monomer having an epoxy group and the styrene monomer, as required.

In particular, the use of acrylonitrile as the other copolymerizable unsaturated monomer is preferable because the compatibility and the adhesive strength are improved.

On the other hand, the use of an epoxy-containing styrene copolymer containing a monomer unit having an amino group or a carboxyl group may cause a gradual progress of a curing reaction during storage, resulting in a decrease in the pot life of the adhesive. Therefore, the content of the monomer unit having an amino group or a carboxyl group is preferably small. In addition, it is not preferable to incorporate a diene monomer such as butadiene, which is a so-called rubber component, because such a diene monomer may decrease weather resistance and heat resistance.

The epoxy-containing styrene copolymer used in the present invention is obtained copolymerizing the monomers described above. The epoxy-containing styrene copolymer may be a random copolymer of the monomer having an epoxy group and the styrene monomer, or a block copolymer or graft copolymer in which polymerized segments of the monomer having an epoxy group and polymerized segments of the styrene monomer are bonded to each other. In the case where another copolymerizable unsaturated monomer unit is contained, the epoxy-containing styrene copolymer may be a copolymer obtained by randomly copolymerizing the monomer having an epoxy group, the styrene monomer, and the other copolymerizable unsaturated monomer, a block copolymer in which polymerized segments of the monomer having an epoxy group, polymerized segments of the styrene monomer, and polymerized segments of the other copolymerizable unsaturated monomer are appropriately combined, or a block copolymer containing polymerized segments of the monomer having an epoxy group and segments in which the styrene monomer and the copolymerizable unsaturated monomer are randomly copolymerized.

The weight-average molecular weight of the epoxy-containing styrene copolymer (B) is not particularly limited, but is preferably about 5,000 to 120,000, more preferably 6,000 to 90,000, and still more preferably 8,000 to 28,000. If the molecular weight is excessively high, the compatibility decreases, and a uniform adhesive solution is difficult to be obtained.

Instead of using the epoxy-containing styrene copolymer (B), in general, the above components are mixed in the form of monomers, which have a good compatibility, and a polymerization reaction is then conducted by heating. However, it takes a long time for the reaction to proceed, and monomers that are not sufficiently subjected to the reaction, a remaining initiating reagent, and a remaining reaction accelerator affect the properties of the resulting hardened material. Furthermore, the reaction gradually proceeds during storage and gelation occurs, resulting in a problem in terms of storage stability. Therefore, this method is not preferable. Accordingly, it is preferable to use the epoxy-containing styrene copolymer (B) having a weight-average molecular weight of 5,000 or more, in which the polymerization reaction has proceeded to a certain degree.

The weight per epoxy equivalent of the epoxy-containing styrene copolymer (B) is preferably 250 g/eq or more and 3,500 g/eq or less, more preferably 3,000 g/eq or less, and still more preferably 2,000 g/eq or less. If the weight per epoxy equivalent exceeds 3,500 g/eq, the compatibility decreases, resulting in a decrease in the homogeneity of the adhesive resin composition, and furthermore, the adhesion property and flame retardancy tend to decrease, though these properties also depend on the molecular weight. Accordingly, the content percentage of the monomer having an epoxy group in the epoxy-containing styrene copolymer (B) is preferably adjusted so that the weight per epoxy equivalent is within the above range, though the content percentage also depends on the molecular weight of the epoxy-containing styrene copolymer.

An epoxy-group containing polymer may be similarly obtained by copolymerizing a monomer having a functional group other than an epoxy group, and then substituting the functional group with an epoxy group. However, in synthesizing a polymer in which an epoxy group is incorporated in a high concentration, the polymer having a weight per epoxy equivalent of 3,500 g/eq or less, preferably 3,000 g/eq or less, and still more preferably 2,000 g/eq or less, such a polymer can be easily obtained by polymerizing a monomer having an epoxy group, and thus this method is preferable.

The content percentage of the styrene monomer unit in the epoxy-containing styrene copolymer (B) is preferably 35% to 98% by mass, and more preferably 45% to 96% by mass. If the content percentage of the styrene monomer unit is decreased, the adhesion property of the resulting adhesive resin composition tends to decrease. On the other hand, if the content percentage of the styrene monomer unit is excessively high, the content percentage of the monomer having an epoxy group becomes relatively low. Consequently, the compatibility with the epoxy resin and/or the phenoxy resin, which is the component (A), and the compatibility with the thermoplastic resin, which is the component (C), decrease. Thus, it becomes difficult to prepare an adhesive in the form of a uniform solution, and furthermore, the adhesion property decreases.

In the case where the epoxy-containing styrene copolymer contains a copolymerizable unsaturated monomer unit other than the monomer unit having an epoxy group and a styrene monomer unit, the content percentage of the other copolymerizable unsaturated monomer unit is less than 40% by mass. In the case where acrylonitrile is incorporated as the other copolymerizable unsaturated monomer and the amount of acrylonitrile is increased in the copolymerization system, an unreacted acrylonitrile monomer tends to remain and is incorporated in the epoxy-containing styrene copolymer, thereby causing adverse effects in some cases. Therefore, the content percentage of acrylonitrile in the epoxy-containing styrene copolymer is preferably 1% to 20% by mass, and more preferably 1% to 15% by mass.

Commercially available epoxy-containing styrene copolymer having the above configuration may be used. Examples thereof include Marproof G series manufactured by NOF CORPORATION.

The epoxy-containing styrene copolymer (B) having the above configuration has a good compatibility with both the epoxy resin and/or phenoxy resin, which is the component (A), and the thermoplastic resin, which is the component (C), and can provide an adhesive solution having good uniformity and storage stability. In addition, a high adhesion property can be exhibited on the basis of the highly uniform adhesive solution. Furthermore, a cross-linked structure can be formed between an epoxy group in the epoxy-containing styrene copolymer (B) and the component (A), and thus good mechanical properties can be imparted.

The content percentage of the epoxy-containing styrene copolymer (B) in the adhesive resin composition is 3% to 25% by mass, preferably 3% to 20% by mass, and more preferably 5% to 16% by mass relative to the resin components contained in the resin composition (i.e., the total amount of the component (A), the component (B), the component (C), and, if another resin is optionally contained, the resin). The reason for this is as follows. If the content percentage of the epoxy-containing styrene copolymer (B) is less than 3% by mass, the effect of improving the adhesion property due to the incorporation of the epoxy-containing styrene copolymer is not obtained. On the other hand, if the content percentage exceeds 25% by mass, the compatibility with the component (A) and the component (C) decreases, resulting in a decrease in the storage stability of the adhesive and the adhesive strength.

The content percentage of the styrene monomer unit in the epoxy-containing styrene copolymer (B) is preferably 1% to 20% by mass, more preferably 3% to 15% by mass, and still more preferably 4% to 12% by mass relative to the amount of resin components contained in the resin composition (i.e., the total amount of the component (A), the component (B), the component (C), and, if another resin is optionally contained, the resin).

### (C) Thermoplastic Resin

Examples of the thermoplastic resin (C) include, but are not particularly limited to, acrylic resins, polystyrene copolymers, polyamide resins, polyamideimide resins, polyester resins, polycarbonate resins, polyphenylene oxide resins, polyphenylene sulfide resins (such as polyphenylene sulfide, polyphenylene sulfide ketone, and polyphenylene sulfide sulfone), polysulfone resins (such as polysulfone and polyethersulfone), polyetherimide resins (such as a poly(N-formylethyleneimine) resin), polyether ether ketone resins, polyacetal resins (such as a polyoxymethylene resin), and ketone resins (such as aliphatic polyketone resins, an acetone-formaldehyde resin, an acetone-furfural resin, and cyclic ketone resins). These thermoplastic resins may be used alone or in combination of two or more resins.

Among these thermoplastic resins, in consideration of the compatibility with both the epoxy resin and/or phenoxy resin (A) and the epoxy-containing styrene copolymer (B) and the adhesion property, polyamide resins are preferably used.

Thermoplastic resins in which phosphorus is incorporated in their molecules are preferable because the amount of flame retardant can be reduced because of their good flame retardancy, and thus it is possible to prevent a decrease in the adhesive strength, the decrease being caused by the incorporation of the flame retardant. Examples of commercially available phosphorus-containing thermoplastic resins include VYLON 237, 337, 537, and 637, and UR3570, all of which are manufactured by TOYOBO CO., LTD.

The polyamide resin can be synthesized by a reaction of a dicarboxylic acid, a diamine, an aminocarboxylic acid, a lactam, and the like. The reaction is not limited to a reaction between one dicarboxylic acid and one diamine. Alternatively, the polyamide resin may be synthesized by using a plurality of dicarboxylic acids and a plurality of diamines.

Examples of the dicarboxylic acid include terephthalic acid, isophthalic acid, orthophthalic acid, naphthalenedicarboxylic acids (1,5-, 2,5-, 2,6-, and 2,7-isomers), biphenyldicarboxylic acids (2,2′-, 3,3′-, and 4,4′-isomers), 4,4′-diphenyl ether dicarboxylic acid, 4,4′-diphenylmethane dicarboxylic acid, 4,4′-diphenyl sulfone dicarboxylic acid, 1,2-bis(phenoxy)ethane-4,4′-dicarboxylic acid, anthracene-dicarboxylic acid (2,5- and 2,6-isomers), phenylene diacetic acids (o-, m-, and p-isomers), phenylene dipropionic acids (o-, m-, and p-isomers), phenylmalonic acid, phenylglutaric acid, diphenylsuccinic acid, oxalic acid, malonic acid, succinic acid, glutaric acid, hexanedioic acid, sebacic acid, decanedicarboxylic acid, maleic acid, fumaric acid, itaconic acid, 1,3-cyclobutanedicarboxylic acid, 1,3-cyclopentanedicarboxylic acid, 1,4-cyclohexanedicarboxylic acid, 1,2-cyclohexanedicarboxylic acid, 1,3-dicarboxymethyl cyclohexane, 1,4-dicarboxymethyl cyclohexane, dicyclohexyl-4,4′-dicarboxylic acid, and dimer acids.

Examples of the diamine include hexamethylenediamine, heptamethylenediamine, p-di-aminomethyl cyclohexane, bis(p-aminecyclohexyl) methane, m-xylene diamine, 1,4-bis(3-aminopropoxy) cyclohexane, piperazine, and isophorone diamine.

Examples of the aminocarboxylic acid include 11-aminoundecanoic acid, 12-aminododecanoic acid, 4-aminomethylbenzoic acid, 4-aminomethylcyclohexane carboxylic acid, 7-aminoenanthic acid, and 9-aminononanoic acid.

Examples of the lactam include ε-caprolactam, ω-laurolactam, α-pyrrolidone, and α-piperidone.

Among these, in particular, polyamides containing a dimer acid as a component are obtained by a common polycondensation of a dimer acid and a diamine. In this case, a dicarboxylic acid other than the dimer acid, such as hexanedioic acid, azelaic acid, or sebacic acid, may be contained as a copolymer component.

As the above-described thermoplastic resins, thermoplastic resins having a glass transition temperature of 70° C. or lower are preferably used. This is because if the glass transition temperature is excessively high, the handleability decreases. In addition, if the glass transition temperature is excessively high, the adhesion property tends to decrease.

### (D) Curing Agent

Any compound used as a curing agent of epoxy resins and phenoxy resins can be used as the curing agent. For example, polyamine curing agents, acid anhydride curing agents, boron trifluoride-amine complexes, imidazole curing agents, aromatic diamine curing agents, carboxylic acid curing agents, and phenol resins are used.

Examples of the polyamine curing agents include aliphatic amine curing agents such as diethylenetriamine and tetraethylene tetramine; alicyclic amine curing agents such as isophorone diamine; aromatic amine curing agents such as diaminodiphenyl methane and phenylenediamine; and dicyandiamide. Examples of the acid anhydride curing agents include acid phthalic anhydride, pyromellitic dianhydride, trimellitic anhydride, and hexahydrophthalic anhydride.

The amount of curing agent mixed is appropriately determined in accordance with the weight per epoxy equivalent of the epoxy resin and/or the phenoxy resin.

### (E) Others

Besides the epoxy resin and/or the phenoxy resin used as the component (A), the epoxy-containing styrene copolymer used as the component (B), the thermoplastic resin used as the component (C), and the curing agent used as the component (D), the adhesive resin composition of the present invention may further contain thermosetting resins other than epoxy resins, for example, phenol resins, melamine resins, and oxazine resins.

Non-halogen flame retardants, preferably, phosphorus flame retardants may also be incorporated.

Examples of the non-halogen flame retardants that can be used in the present invention include phosphorus compounds such as phosphoric esters, phosphate amides, phosphazenes, and 9,10-dihydro-9-oxa-10-phosphaphenanthrene-10-oxide. Among these, phosphazenes are preferably used from the standpoint of the phosphorus concentration and the solubility in a solvent. The term “phosphazene” is a common name of a group of compounds having a double bond and containing phosphorus and nitrogen as constituent elements. The phosphazene is not particularly limited as long as the compound has a phosphazene structure in its molecule. The phosphazene may be a cyclophosphazene having a cyclic structure, or a linear polymer or oligomer obtained by conducting ring-opening polymerization of the cyclophosphazene.

In the case where a non-halogen flame retardant is incorporated, the adhesion property decreases with an increase in the content percentage of the flame retardant. Thus, the content percentage of the non-halogen flame retardant is preferably, at a maximum, 30 parts by mass or less per 100 parts by mass of the resins.

It should be noted that, preferably, a metalhydroxide (inorganic filler) such as magnesium hydroxide or aluminum hydroxide is not incorporated as the non-halogen flame retardant because such a metalhydroxide causes a decrease in the adhesion property.

### [Preparation of Adhesive Resin Composition]

The adhesive resin composition of the present invention is prepared by mixing the components (A) to (D) described above, and as required, other thermosetting resins, a non-halogen flame retardant, and other additives.

The adhesive resin composition is preferably prepared so that the phosphorus content percentage in the adhesive resin composition is 3.1% to 4.5% by mass.

In addition, a hardening accelerator, a silane coupling agent, a leveling agent, an antifoaming agent, and other additives may be mixed as required. However, addition of a hardening accelerator tends to shorten the pot life of the adhesive and degrade the adhesion property. Therefore, it is undesirable to mix a hardening accelerator. Furthermore, addition of inorganic filler tends to degrade the adhesion property and migration characteristics, and thus, it is undesirable to mix inorganic filler.

The adhesive resin composition of the present invention is usually dissolved in an organic solvent, and used as an adhesive solution. Examples of the organic solvent that can be used include toluol, methanol, ethanol, isopropanol, acetone, dioxolane, hexane, triethylamine, isobutyl acetate, butyl acetate, ethyl acetate, methyl ethyl ketone (MEK), methyl isobutyl ketone, cellosolves, ethylene glycol, dimethylformamide (DMF), xylene, and N-methylpyrrolidone.

The solid content concentration in the adhesive solution is preferably 10% to 50% by mass, though the concentration depends on the coating method.

The adhesive resin composition of the present invention having the above configuration can provide a one-part adhesive which has a high adhesion property and in which resin components are homogeneously mixed without separation or aggregation because of the coexistence of the epoxy-containing styrene copolymer which is the component (B).

### [Applications]

The adhesive resin composition of the present invention having the configuration described above can provide a solution-type adhesive solution that is halogen-free, that satisfies flame retardancy of the V-0 class or the VTM-0 class in the UL-94 standard, and that can exhibit a good adhesion property. Accordingly, the adhesive resin composition of the present invention is useful as an adhesive used for a laminate such as an adhesive sheet or a coverlay, a flexible printed wiring board, or the like.

In particular, the adhesive resin composition of the present invention is a transparent solution-type adhesive and is good in terms of storage property. Thus, the adhesive resin composition of the present invention can be suitably used in production sites as a solution-type adhesive that is used by being applied onto a base material film.

A flexible printed wiring board includes a plurality of layers produced by bonding an insulating film to a metallic foil, with a hardened material of the adhesive resin composition of the present invention therebetween. Specifically, the flexible printed board can be formed by lamination of, for example, a product (so-called three-layer substrate) prepared by applying the adhesive resin composition of the present invention onto an insulating film, drying the adhesive resin composition (to a semi-hardened state), further laminating the insulating film with a metallic foil, and then by heat-setting the resulting laminate; a product (so-called coverlay) prepared by applying the adhesive resin composition of the present invention onto an insulating film, drying the adhesive resin composition (to a semi-hardened state), and covering an exposed surface of the resulting adhesive layer with an insulating film called a separator; and a product (so-called adhesive sheet) prepared by applying the adhesive resin composition of the present invention onto a separator or a base material film, drying the adhesive resin composition (to a semi-hardened state), and covering an exposed surface with a separator; and heat-setting the resulting laminate. Note that the separator is removed when the lamination is performed.

Herein, the term “semi-hardened state” refers to a state in which an adhesive resin composition has an adhesion property. The semi-hardened state is formed by heating the adhesive resin composition of the present invention, for example, at 100° C. to 180° C. for two minutes. The term “heat-set state” refers to a state in which a thermosetting resin (epoxy resin) is cured by a reaction with a curing agent under heating. The heat-set state is formed by heating an adhesive layer in the semi-hardened state, for example, at 140° C. to 180° C. for 10 minutes to several hours, and further applying a pressure as required. The suitable heating time varies depending on the components and the application (for example, a substrate, a coverlay, a bonding film, or the like) of the adhesive.

It is sufficient that the three-layer substrate of the present invention includes an insulating film and a metallic foil bonded to at least one surface of the insulating film. The three-layer substrate may have a three-layer structure (so-called three-layer single-sided substrate) including an insulating film, an adhesive layer, and a metallic foil layer. Alternatively, the three-layer substrate may have a five-layer structure (so-called three-layer double-sided substrate) including a metallic foil, an adhesive layer, an electrically insulating film, an adhesive layer, and a metallic foil layer.

Examples of the insulating film include a polyimide film, a polyester film, a polyetheretherketone film, and a polyphenylene sulfide film.

Examples of the metallic foil include a copper foil and an aluminum foil. A copper foil is preferably used.

The coverlay film is a laminate used as a material that covers a surface of a flexible copper-clad laminated board, on which a wiring pattern is formed by processing a copper foil of the flexible copper-clad laminated board, so that the material protects the wiring. The coverlay film includes an insulating film and an adhesive layer in the semi-hardened state, the adhesive layer being composed of the adhesive resin composition of the present invention and provided on the insulating film. Usually, a separator having a releasing property is bonded onto the adhesive layer.

The adhesive sheet includes a separator or a base material film in some cases and an adhesive layer in the semi-hardened state, the adhesive layer being composed of the adhesive resin composition of the present invention and stacked on the separator or the base material film, and is used for lamination of a substrate or bonding of a reinforcing plate. The base material film is selected in accordance with the application, and may be a heat-resistant, insulating film such as a polyimide film, a fiberglass reinforced resin sheet, or a prepreg sheet including a nonwoven fabric or the like as a base material.

### EXAMPLES

Best modes for carrying out the present invention will now be described by way of Examples. The Examples do not limit the scope of the present invention.

### [Methods for Measuring and Evaluating Adhesive Resin Composition]

### (1) Compatibility

A prepared adhesive solution was visually observed. In the case where a transparent solution was obtained (however, opacity with a degree of obscured glass was acceptable), the adhesive solution was evaluated as “◯”. In the case where white turbidness was observed, and separation was observed after the adhesive solution was left to stand for one week, the adhesive solution was evaluated as “Δ”. In the case where a separation layer was generated within two hours even after forced mixing under stirring, the adhesive solution was evaluated as “x”.

### (2) Peel Strength

A prepared adhesive solution was applied onto a surface of a polyimide film having a thickness of 25 μm so that the thickness of an adhesive layer after drying was 20 μm, and dried at 150° C. for two minutes to form the adhesive layer in the semi-hardened state. A rolled copper foil having a thickness of 18 μm was stacked on this adhesive layer in the semi-hardened state. Subsequently, heating was performed at 160° C. for 40 minutes by hot pressing at a pressure of 3 MPa to prepare a flexible printed wiring board. For the prepared flexible printed wiring board, a peel strength (N/cm) was measured by pulling from the copper foil side to peel off the copper foil from the polyimide film at 23° C. in accordance with Japan Industrial Standard (JIS) C 6481.

Note that when the peel strength exceeded 20 N/cm, the copper foil was broken and the peel strength could not be measured.

### (3) Flame Retardancy

An evaluation test of flame retardancy was conducted in accordance with UL-94 using a laminate including the polyimide film and the semi-hardened adhesive layer prepared in (2), the laminate being prepared by being heated at 160° C. for 40 minutes without applying a pressure and without being laminated with a copper foil. A laminate that conformed to the above standard (V-0 class) was evaluated as “OK”. A laminate that did not conform to the standard was evaluated as “NG”.

### [Preparation and Evaluation of Adhesive Resin Composition Nos. 1 to 13]

A polyamide resin (C), a phosphorus-containing epoxy/phenoxy resin (A), and an epoxy-containing styrene copolymer (B) were mixed in the proportions shown in Table I, a phosphazene functioning as a flame retardant and a curing agent were further added to the mixture, and the resulting mixture was dissolved in a solvent (methyl ethyl ketone and dimethylformamide) while stirring to prepare adhesive solution Nos. 1 to 13 having a solid content concentration of 30% by mass.

As the phosphorus-containing epoxy/phenoxy resin, a 1:1 mixture of a phosphorus-containing epoxy resin FX289 and a phosphorus-containing phenoxy resin ERF001 manufactured by Tohto Kasei CO., LTD. was used. As the epoxy-containing styrene copolymer, “Marproof G0250S” (molecular weight: 20,000, weight per epoxy equivalent: 310 g/eq, content percentage of styrene monomer unit in epoxy-containing styrene copolymer: 54% by mass) manufactured by NOF CORPORATION was used in Nos. 1 to 8, and “Blemmer CP5SA” (molecular weight: 10,000, weight per epoxy equivalent: 2,500 g/eq, content percentage of styrene monomer unit in epoxy-containing styrene copolymer: 85% by mass, content percentage of acrylonitrile monomer unit in epoxy-containing styrene copolymer: 10% by mass) manufactured by NOF CORPORATION was used in Nos. 9 to 13. As the phosphazene, SPB100 manufactured by Otsuka Chemical Co., Ltd. was used, and the amount of phosphazene mixed was determined so that the phosphorus content percentage relative to the solid content of each adhesive resin composition was 3.5% by mass. As the curing agent, trimellitic acid manufactured by Mitsubishi Chemical Corporation was used, and mixed in an appropriate amount calculated from the weight per epoxy equivalent.

The compatibility and the peel strength of each of the prepared adhesive solutions Nos. 1 to 13 were measured on the basis of the above evaluation methods. Table I shows the measurement results together with the resin blending compositions.

TABLE I

| No | | 1 | 2 | 3 | 4 | 5 | 6 | 7 | 8 | 9 | 10 | 11 | 12 | 13 |
|---|---|---|---|---|---|---|---|---|---|---|---|---|---|---|
| Resin | Polyamid (C) | 50 | 50 | 50 | 50 | 50 | 50 | 50 | 50 | 50 | 50 | 50 | 50 | 50 |
| composition | Phosphorus-containing | 100 | 95 | 90 | 85 | 80 | 70 | 60 | 50 | 90 | 85 | 80 | 70 | 60 |
| (parts) | epoxy/phenoxy resin (A) | | | | | | | | | | | | | |
| | Epoxy-containing styrene | 0 | 5 | 10 | 15 | 20 | 30 | 40 | 50 | 10 | 15 | 20 | 30 | 40 |
| | copolymer (B) | | | | | | | | | | | | | |
| Content percentage of (B) in | | 0 | 3.3 | 6.7 | 10 | 13.3 | 20.0 | 26.7 | 33.3 | 6.7 | 10 | 13.3 | 20 | 26.7 |
| resin components (mass %) | | | | | | | | | | | | | | |
| Content percentage of styrene | | 0 | 1.8 | 3.6 | 5.4 | 7.2 | 10.8 | 14.4 | 18.0 | 5.7 | 8.5 | 11.3 | 17 | 22.7 |
| monomer unit in resin | | | | | | | | | | | | | | |
| components (mass %) | | | | | | | | | | | | | | |
| Evaluation | Compatibility | ○ | ○ | ○ | ○ | ○ | Δ | X | X | ○ | ○ | ○ | ○ | X |
| | Peel strength (N/cm) | 2.2 | 10.3 | 14.8 | >20 | >20 | 9.1 | 6.2 | <1 | 17.4 | >20 | >20 | >20 | 7.2 |

As is apparent from Table I, with an increase in the content of the epoxy-containing styrene copolymer, the compatibility decreased. In the case where the content percentage of the epoxy-containing styrene copolymer relative to the resin components (the total sum amount of the component (A), the component (B), and the component (C)) in the adhesive resin composition was 20% by mass (No. 6), the transparency of the adhesive solution was impaired. Furthermore, in the case where the content percentage of the epoxy-containing styrene copolymer exceeded 25% by mass (Nos. 7, 8, and 13), the adhesive solutions were separated into two layers, and the adhesive solutions could not be applied onto base material films as they are.

As for No. 12 containing the epoxy-containing styrene copolymer in a content percentage of 20% by mass, which was the same as that of No. 6, the compatibility was improved and the transparency was maintained by incorporating acrylonitrile as another copolymerizable unsaturated monomer. On the other hand, the peel strength tended to improve with the increase in the content of the epoxy-containing styrene copolymer.

Accordingly, it is found that, in order to effectively achieve the effect of increasing the peel strength due to the epoxy-containing styrene copolymer, it is effective to adjust the content percentage of the epoxy-containing styrene copolymer relative to the amount of resin components to be 3% to 25% by mass, and preferably 3% to 20% by mass.

### [Preparation and Evaluation of Adhesive Resin Composition Nos. 21 to 30]

Epoxy-containing styrene copolymers having characteristics show in Table II were incorporated in the proportions shown in Table II, and were dissolved in a solvent (methyl ethyl ketone and dimethylformamide) while stiffing to prepare adhesive solution Nos. 21 to 28 having a solid content concentration of 30% by mass (the content percentage of each of the epoxy-containing styrene copolymers in the resin components was 6.7% by mass).

The epoxy-containing styrene copolymers used in Nos. 21 to 25 were random copolymers of glycidyl methacrylate and styrene. The epoxy-containing styrene copolymers used in Nos. 26 and 27 were ternary copolymers of glycidyl methacrylate, styrene, and acrylonitrile. The epoxy-containing styrene copolymer used in No. 28 was a 1:1 mixture of the epoxy-containing styrene copolymer used in No. 21 and the epoxy-containing styrene copolymer used in No. 23.

Regarding a polyamide resin, a phosphorus-containing epoxy/phenoxy resin, and a flame retardant, the same polyamide resin, phosphorus-containing epoxy resin, and flame retardant as those used in the adhesive resin composition No. 1 were used.

Furthermore, for comparison, adhesive solutions were prepared as in No. 21 using adhesive resin composition Nos. 29 and 30 that contained no epoxy-containing styrene copolymer which is the component (B).

The compatibility, the peel strength, and the flame retardancy of each of the prepared adhesive solutions were measured and evaluated on the basis of the above evaluation methods. Table II shows the measurement results together with the resin blending compositions and characteristics of the epoxy-containing styrene copolymers.

TABLE II

| No | | 21 | 22 | 23 | 24 | 25 | 26 | 27 | 28 | 29 | 30 |
|---|---|---|---|---|---|---|---|---|---|---|---|
| Resin | Polyamid (C) | 100 | 100 | 100 | 100 | 100 | 100 | 100 | 100 | 100 | 100 |
| composition | Phosphorus-containing | 180 | 180 | 180 | 180 | 180 | 180 | 180 | 180 | 200 | 200 |
| (parts) | epoxy/phenoxy resin (A) | | | | | | | | | | |
| | Styrene copolymer (B) | 20 | 20 | 20 | 20 | 20 | 20 | 20 | 20 | 0 | 0 |
| Characteristics | Weight-average | 9000 | 11000 | 20000 | 100000 | 100000 | 100000 | 100000 | 14500 | — | — |
| of styrene | molecular weight | | | | | | | | | | |
| copolymer | Weight per epoxy | 530 | 1000 | 310 | 1700 | 3300 | 3300 | 2500 | 420 | — | — |
| | equivalent (g/eq) | | | | | | | | | | |
| | Content percentage of | 73 | 86 | 54 | 92 | 96 | 85 | 85 | 64 | — | — |
| | styrene monomer unit | | | | | | | | | | |
| | (mass %) | | | | | | | | | | |
| | Content percentage of | 27 | 14 | 46 | 8 | 4 | 5 | 5 | 36 | — | — |
| | epoxy monomer unit | | | | | | | | | | |
| | (mass %) | | | | | | | | | | |
| Content percentage of styrene | | 4.9 | 5.8 | 3.6 | 6.1 | 6.4 | 5.7 | 5.7 | 4.2 | — | — |
| monomer unit in resin | | | | | | | | | | | |
| components (maas %) | | | | | | | | | | | |
| Phosphorus content percentage in | | 3.5 | 3.5 | 3.5 | 3.5 | 3.5 | 3.5 | 3.5 | 3.5 | 3.5 | 3.0 |
| composition (mass %) | | | | | | | | | | | |
| Evaluation | Compatibility | ○ | ○ | ○ | Δ | Δ | ○ | ○ | ○ | ○ | ○ |
| | Peel strength (N/cm) | 11 | 14.9 | 14.8 | 14.6 | 12.6 | 18 | 17.4 | 12.6 | 2.2 | 6.4 |
| | Flame retardancy | OK | OK | OK | OK | OK | OK | OK | OK | OK | NG |

The resin composition (No. 29), in which no epoxy-containing styrene copolymer was incorporated, did not satisfy the peel strength. Although the peel strength could be increased by decreasing the content of the flame retardant, the degree of improvement was insufficient. In this case, the phosphorus content percentage was excessively low, and the flame retardancy could not be satisfied (No. 30).

In contrast, the resin compositions (Nos. 21 to 28) of Examples of the present invention, in which an epoxy-containing styrene copolymer was incorporated, each of the resin compositions satisfied the flame retardancy and achieved a high adhesive strength. However, when the weight-average molecular weight was as high as 100,000 and the content percentage of the styrene monomer unit was high, the compatibility tended to decrease (Nos. 24 and 25). On the other hand, even when epoxy-containing styrene copolymers having a molecular weight of 100,000 were used, Nos. 26 and 27, in which epoxy-containing styrene copolymers containing acrylonitrile were used, exhibited a satisfactory compatibility.

### INDUSTRIAL APPLICABILITY

The adhesive resin composition of the present invention has a good adhesion property and flame retardancy, and does not cause a problem of variations in the adhesion property among products in production lines or problems in terms of pot life and storage property in that stirring, washing of devices, and the like must be performed each time the resin composition is used. Thus, the adhesive resin composition of the present invention is useful for continuous or intermittent use in production lines and the like.

### CITATION LIST

### Patent Literature

PTL 1: Japanese Unexamined Patent Application Publication No. 2003-176470

PTL 2: Japanese Unexamined Patent Application Publication No. 2005-248134

PTL 3: International Publication No. WO01/60938

1. An adhesive resin composition comprising (A) an epoxy resin and/or a phenoxy resin; (B) an epoxy-containing styrene copolymer containing a monomer unit having an epoxy group and a styrene monomer unit; (C) a thermoplastic resin; and (D) a curing agent,
wherein the content percentage of the epoxy-containing styrene copolymer (B) relative to the total amount of the resin components contained in the adhesive resin composition is 3% to 25% by mass and the epoxy-containing styrene copolymer (B) has a weight-average molecular weight of 6,000 to 90,000.

2. The adhesive resin composition according to claim 1, wherein the content percentage of the styrene monomer unit in the epoxy-containing styrene copolymer (B) is 35% to 98% by mass.

3. The adhesive resin composition according to claim 1, wherein the content percentage of the styrene monomer unit relative to the total amount of the resin components contained in the adhesive resin composition is 1% to 20% by mass.

4. The adhesive resin composition according to claim 1, wherein the epoxy-containing styrene copolymer (B) further contains an acrylonitrile monomer unit.

5. The adhesive resin composition according to claim 1, wherein the epoxy-containing styrene copolymer (B) has a weight per epoxy equivalent of 250 g/eq or more and 3,500 g/eq or less.

6. The adhesive resin composition according to claim 1, wherein a monomer having an epoxy group in the epoxy-containing styrene copolymer (B) is glycidyl (meth)acrylate.

7. The adhesive resin composition according to claim 1, wherein the epoxy resin and/or phenoxy resin (A) is a phosphorus-containing epoxy resin and/or a phosphorus-containing phenoxy resin.

8. The adhesive resin composition according to claim 1, further comprising a phosphorus flame retardant, wherein the phosphorus content percentage relative to the solid content of the resin composition is 3.1% to 4.5% by mass.

9. A laminate comprising a base material film and an adhesive layer disposed on the base material film, the adhesive layer being composed of the adhesive resin composition according to claim 1.

10. A flexible printed wiring board comprising the laminate according to claim 9.

11. The adhesive resin composition according to claim 2, further comprising a phosphorus flame retardant, wherein the phosphorus content percentage relative to the solid content of the resin composition is 3.1% to 4.5% by mass.

12. The adhesive resin composition according to claim 3, further comprising a phosphorus flame retardant, wherein the phosphorus content percentage relative to the solid content of the resin composition is 3.1% to 4.5% by mass.

13. The adhesive resin composition according to claim 4, further comprising a phosphorus flame retardant, wherein the phosphorus content percentage relative to the solid content of the resin composition is 3.1% to 4.5% by mass.

14. The adhesive resin composition according to claim 5, further comprising a phosphorus flame retardant, wherein the phosphorus content percentage relative to the solid content of the resin composition is 3.1% to 4.5% by mass.

15. The adhesive resin composition according to claim 6, further comprising a phosphorus flame retardant, wherein the phosphorus content percentage relative to the solid content of the resin composition is 3.1% to 4.5% by mass.

16. The adhesive resin composition according to claim 7, further comprising a phosphorus flame retardant, wherein the phosphorus content percentage relative to the solid content of the resin composition is 3.1% to 4.5% by mass.
